(19) United States
(12) Patent Application Publication
(10) Pub. No.: US 2019/0051494 A1
(43) Pub. Date: Feb. 14, 2019

(54) MULTI CHARGED PARTICLE BEAM WRITING APPARATUS

(71) Applicant: NuFlare Technology, Inc., Yokohama-shi (JP)

(72) Inventor: Hiroshi Yamashita, Sagamihara-shi (JP)

(73) Assignee: NuFlare Technology, Inc., Yokohama-shi (JP)

(21) Appl. No.: 16/057,153

(22) Filed: Aug. 7, 2018

(30) Foreign Application Priority Data
Aug. 10, 2017 (JP) 2017-155470

(51) Int. Cl. H01J 37/317; H01J 37/09; H01J 37/04

(52) U.S. Cl. CPC H01J 37/3177; H01J 37/09; H01J 2237/31774; H01J 2237/0435; H01J 37/045

(57) ABSTRACT

In one embodiment, a multi charged particle beam writing apparatus includes an emitter emitting a charged particle beam, a shaping aperture array member having a plurality of first apertures, and allowing the charged particle beam to pass through the first apertures to form multiple beams, an X-ray shielding plate having a plurality of second apertures through each of which a corresponding one of the multiple beams that have passed through the first apertures passes, and a blanking aperture array member having a plurality of third apertures through each of which a corresponding one of the multiple beams that have passed through the first apertures and the second apertures passes, the blanking aperture array member including a blanker performing blanking deflection on the corresponding beam. The X-ray shielding plate blocks X-rays produced by irradiation of the shaping aperture array member with the charged particle beam.

### CROSS REFERENCE TO RELATED APPLICATION

This application is based upon and claims benefit of priority from the Japanese Patent Application No. 2017-155470, filed on Aug. 10, 2017, the entire contents of which are incorporated herein by reference.

### FIELD

The present invention relates to a multi charged particle beam writing apparatus.

### BACKGROUND

With an increase in the density of transistor, the required linewidths of circuits of semiconductor devices become finer year by year. To form a desired circuit pattern of a semiconductor device, a method is employed in which a precise mask (or also particularly called reticle, which is used in a stepper or a scanner) pattern formed on a quartz substrate is transferred to a wafer by using a reduction projection exposure apparatus. The high-precision mask pattern is written by using an electron-beam writing apparatus, in which a so-called electron-beam lithography technique is employed.

A writing apparatus using multiple beams enables irradiation with many beams at once as compared with writing using a single electron beam, and thus markedly increases throughput. Examples of such multi-beam writing apparatuses include a multi-beam writing apparatus including a blanking aperture array member. In such a multi-beam writing apparatus, for example, an electron beam emitted from a single electron gun passes through a shaping aperture array member having a plurality of apertures, thus forming multiple beams (a plurality of electron beams). Each of the multiple beams passes through a corresponding one of blankers arranged in a blanking aperture array member. The blanking aperture array member includes pairs of electrodes for individually deflecting the beams and an aperture for beam passage between each pair of electrodes. One of the pair of electrodes (the blanker) is held at ground potential, and the other one of the electrodes is switched between the ground potential and a potential other than the ground potential, thus achieving individual blanking deflection of the electron beam that is to pass through the blanker. The electron beam deflected by the blanker is blocked. The electron beam that has not been deflected is applied to a sample. The blanking aperture array member has a circuit element for independent control of the potentials of the electrodes of the blankers.

When the electron beam is stopped by the shaping aperture array member for forming multiple beams, bremsstrahlung X-ray radiation is produced. If the X-rays are applied to the blanking aperture array member, total ionizing dose (TID) effects may deteriorate the electrical characteristics of metal oxide semiconductor field-effect transistors (MOSFET) included in the circuit element, causing the circuit element to operate incorrectly.

### BRIEF DESCRIPTION OF THE DRAWINGS

FIG. 1 is a schematic diagram of a multi-charged-particle-beam writing apparatus according to an embodiment of the present invention;

FIG. 2 is a plan view of a shaping aperture array member;

FIG. 3 is a sectional view illustrating the shaping aperture array member and an X-ray shielding plate;

FIG. 4 is a graph showing the relationship between the effective thickness of the X-ray shielding plate and the X-ray dose absorbed in a silicon oxide film;

FIG. 5 is a sectional view of X-ray shielding plates according to a modification;

FIG. 6 is a schematic diagram of a multi-charged-particle-beam writing apparatus according to a modification;

FIG. 7 is a sectional view of an X-ray shielding plate according to a modification; and

FIG. 8 is a sectional view of X-ray shielding plates according to a modification.

### DETAILED DESCRIPTION

In one embodiment, a multi charged particle beam writing apparatus includes an emitter emitting a charged particle beam, a shaping aperture array member having a plurality of first apertures, and allowing the charged particle beam to pass through the first apertures to form multiple beams, an X-ray shielding plate having a plurality of second apertures through each of which a corresponding one of the multiple beams that have passed through the first apertures passes, and a blanking aperture array member having a plurality of third apertures through each of which a corresponding one of the multiple beams that have passed through the first apertures and the second apertures passes, the blanking aperture array member including a blanker performing blanking deflection on the corresponding beam. The X-ray shielding plate blocks X-rays produced by irradiation of the shaping aperture array member with the charged particle beam.

An embodiment of the present invention will be described below with reference to the drawings. In the embodiment, a configuration using an electron beam as an example of a charged particle beam will be described. The charged particle beam is not limited to the electron beam. For example, the charged particle beam may be an ion beam.

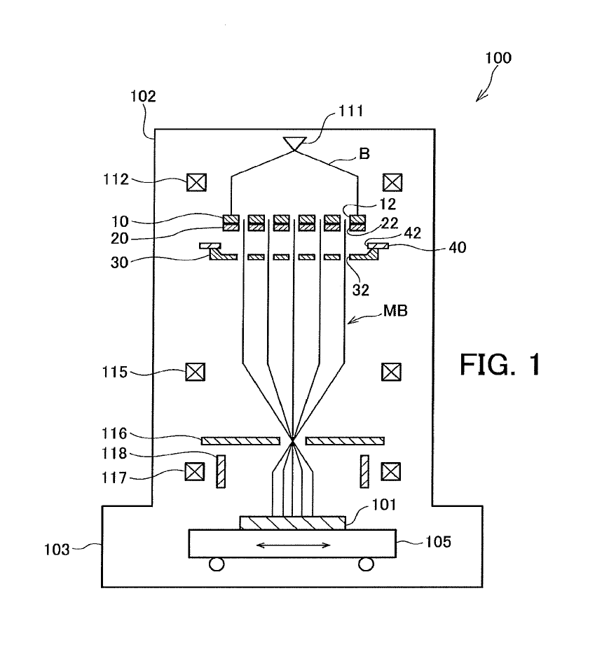

FIG. 1 is a schematic diagram illustrating an exemplary configuration of a writing apparatus according to the embodiment. A writing apparatus 100 illustrated in FIG. 1 is an example of a multi-charged-particle-beam writing apparatus. The writing apparatus 100 includes an electron optical column 102 and a writing chamber 103. The electron optical column 102 accommodates an electron gun 111, an illumination lens 112, a shaping aperture array member 10, an X-ray shielding plate 20, a blanking aperture array member 30, a reducing lens 115, a limiting aperture member 116, an objective lens 117, and a deflector 118.

The blanking aperture array member 30 is mounted (disposed) on a mounting substrate 40. The mounting substrate 40 has an aperture 42 for passage of electron beams (multiple beams MB) in central part of the substrate.

The writing chamber 103 accommodates an X-Y stage 105. A sample 101 that serves as a writing target substrate when writing is performed, for example, a mask blank that is coated with resist and that has not yet been subjected to writing, is placed on the X-Y stage 105. Examples of the sample 101 include an exposure mask used to fabricate a semiconductor device and a semiconductor substrate (silicon wafer) on which semiconductor devices are to be fabricated.

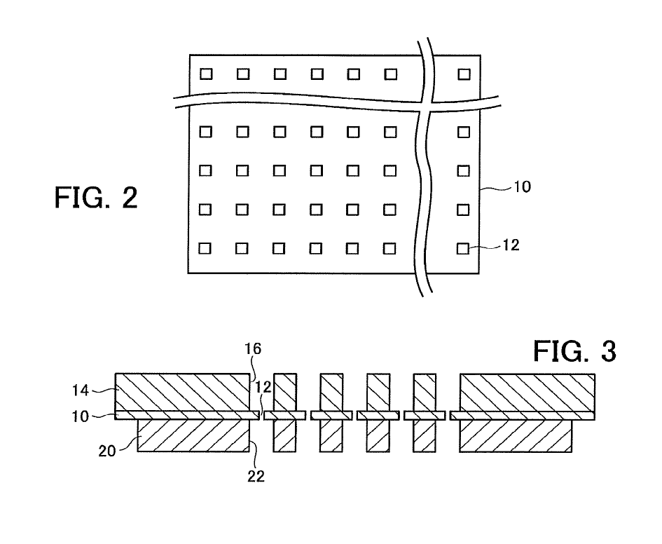

As illustrated in FIG. 2, the shaping aperture array member 10 has apertures (first apertures) 12 arranged in an array of m columns extending in the longitudinal direction of the shaping aperture array member 10×n rows extending in the lateral direction thereof (m, n≥2) at a predetermined pitch. The apertures 12 have the same shape and dimensions and are rectangular. The apertures 12 may have a circular shape. An electron beam B partially passes through these apertures 12, thus forming the multiple beams MB.

As illustrated in FIG. 3, the shaping aperture array member 10 is integrated with a pre-aperture array member 14 such that the pre-aperture array member 14 is disposed on an upper surface of the shaping aperture array member 10. The pre-aperture array member 14 has apertures 16 for passage of electron beams such that the apertures 16 are aligned with the respective apertures 12 of the shaping aperture array member 10. The apertures 16 have a larger diameter than the apertures 12. The apertures 12 communicate with the apertures 16.

Each of the shaping aperture array member 10 and the pre-aperture array member 14 is formed of, for example, a silicon substrate having apertures.

The X-ray shielding plate 20 is disposed on a lower surface (surface facing downstream in a beam travel direction) of the shaping aperture array member 10. For example, the X-ray shielding plate 20 is secured to the shaping aperture array member 10 with silver paste. The X-ray shielding plate 20 has apertures 22 (second apertures) for passage of electron beams such that the apertures 22 are aligned with the respective apertures 12 of the shaping aperture array member 10. The pitch of the apertures 22 (the distance between the centers of the adjacent apertures 22) is the same as that of the apertures 12.

The diameter of the apertures 22 is equal to or larger than that of the apertures 12. The apertures 22 communicate with the apertures 12. In view of the accuracy of alignment of the apertures 12 with the apertures 22, preferably, the apertures 22 have a larger diameter than the apertures 12 so that the X-ray shielding plate 20 does not obstruct the apertures 12.

The X-ray shielding plate 20 attenuates X-rays produced by braking radiation (bremsstrahlung), caused when the electron beam is stopped by the shaping aperture array member 10 (and the pre-aperture array member 14), to prevent a circuit element of the blanking aperture array member 30 from being damaged and prevent resist on the sample 101 to be exposed to the X-rays.

The larger the atomic number of a material of the X-ray shielding plate 20, the higher the X-ray absorption rate of the X-ray shielding plate 20. It is therefore preferred that the X-ray shielding plate 20 be made of heavy metal, such as tungsten, gold, tantalum, lead, hafnium, or platinum.

When shaping the multiple beams MB, the shaping aperture array member 10 interrupts most of the electron beam B and thus generates heat and thermally expands. Preferably, the X-ray shielding plate 20 adjoining the shaping aperture array member 10 thermally expands to the same extent as that to which the shaping aperture array member 10 thermally expands. For example, if the shaping aperture array member 10 is made of silicon, it is preferred that the X-ray shielding plate 20 be made of tungsten, which has a thermal expansion coefficient (linear expansion coefficient) close to that of silicon.

The blanking aperture array member 30 is disposed under the X-ray shielding plate 20. The blanking aperture array member 30 has passage holes (third apertures) 32 aligned with the respective apertures 12 of the shaping aperture array member 10. In each passage hole 32, a blanker including two electrodes paired is disposed. One of the electrodes of the blanker is held at ground potential, and the other one of the electrodes is switched between the ground potential and a different potential. Each of the electron beams passing through the respective passage holes 32 is independently deflected by a voltage (electric field) applied to the blanker.

As described above, each of the blankers performs blanking deflection on the corresponding one of the multiple beams MB that have passed through the apertures 12 of the shaping aperture array member 10.

The electron beam B emitted from the electron gun 111 (emitter) is caused by the illumination lens 112 to be applied substantially perpendicular to the entire shaping aperture array member 10. The electron beam B passes through the multiple apertures 12 of the shaping aperture array member 10, thus forming a plurality of electron beams (multiple beams) MB. The multiple beams MB pass through the apertures 22 of the X-ray shielding plate 20 and then pass through the respective blankers of the blanking aperture array member 30.

The multiple beams MB that have passed through the blanking aperture array member 30 are reduced by the reducing lens 115, and travel toward a central opening of the limiting aperture member 116. Electron beams deflected by the blankers are deviated from the central opening of the limiting aperture member 116 and are accordingly blocked by the limiting aperture member 116. In contrast, electron beams that have not been deflected by the blankers pass through the central opening of the limiting aperture member 116. Turning on and off the blankers performs blanking control to control switching between ON and OFF states of the beams.

As described above, the limiting aperture member 116 blocks the beams deflected in a beam OFF state by the blankers. A period between the time when the beams enter a beam ON state and the time when the beams are switched to the beam OFF state corresponds to a one-time shot with the beams passing through the limiting aperture member 116.

The multiple beams that have passed through the limiting aperture member 116 are focused by the objective lens 117, so that the shapes (object plane images) of the apertures 12 of the shaping aperture array member 10 are projected on the sample 101 (image plane) at a desired reduction rate. The multiple beams are collectively deflected in the same direction by the deflector 118 and are then applied to respective beam irradiation positions on the sample 101. While the X-Y stage 105 is continuously moved, the deflector 118 performs control such that the beam irradiation positions follow the movement of the X-Y stage 105.

The multiple beams to be applied at a time are ideally arranged at a pitch obtained by multiplying the pitch of the apertures 12 of the shaping aperture array member 10 by the above-described desired magnification ratio. The writing apparatus 100 performs a writing operation in a raster-scan manner such that beam shots are successively and sequentially applied. To write a desired pattern, the writing apparatus 100 performs the blanking control to switch beams unnecessary for the pattern to the beam OFF state.

In the present embodiment, the X-ray shielding plate 20 prevents the X-rays radiated from the shaping aperture array member 10 from being applied to, for example, the circuit element of the blanking aperture array member 30. This prevents the circuit element from operating incorrectly due to X-rays and allows the lifetime (duration during which the circuit element electrically operates normally) of the circuit element to be extended.

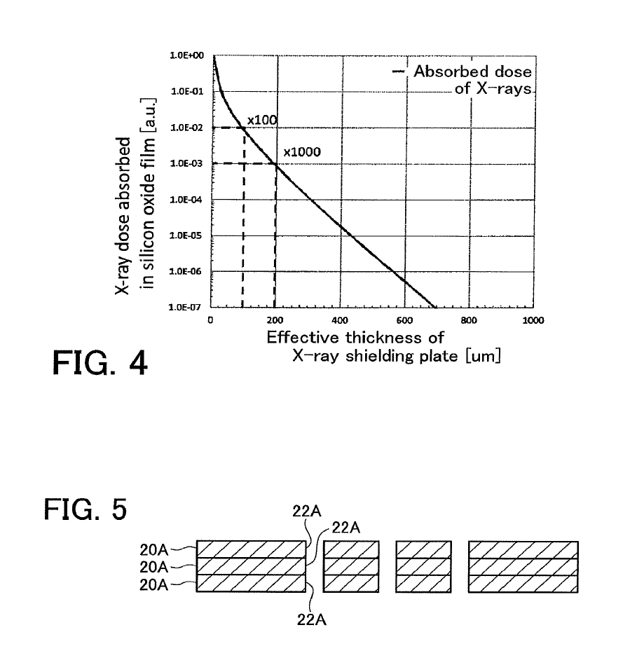

The thicker the X-ray shielding plate 20, the higher the X-ray absorption rate of the X-ray shielding plate 20. FIG. 4 is a graph showing the relationship between the thickness of the X-ray shielding plate 20 and the X-ray dose absorbed in a silicon oxide film disposed under the X-ray shielding plate 20 (downstream of the X-ray shielding plate 20 in the beam travel direction). The relationship was obtained from experiment and simulation. The silicon oxide film was intended to serve as a gate insulating film or an element isolation layer of a transistor included in the circuit element of the blanking aperture array member 30.

In the simulation, tungsten was used as a material for the X-ray shielding plate 20. The horizontal axis of the graph of FIG. 4 represents the effective thickness of the X-ray shielding plate 20. The X-ray shielding plate 20 has the multiple apertures 22, and the effective thickness of the X-ray shielding plate 20 is a thickness based on the opening ratio (volume). For example, when the opening ratio of the apertures 22 to the X-ray shielding plate 20 having a thickness of 400 μm is 50%, the effective thickness is 200 μm. When the opening ratio is 25%, the effective thickness is 300 μm.

The dose D of X-rays absorbed in the silicon oxide film can be obtained by using the following expression.

D=kt∫ef(e)g(e)h(e)de [Math. 1]

In the above-described expression, e denotes the energy of X-rays, k denotes the coefficient, t denotes the beam irradiation time, f(e) denotes the actually measured intensity of braking X-ray radiation, g(e) denotes the transmittance of X-rays through the X-ray shielding plate, and h(e) denotes the function representing the X-ray absorption rate of the silicon oxide film.

As shown in FIG. 4, the greater the thickness (effective thickness) of the X-ray shielding plate 20, the higher the X-ray absorption rate of the X-ray shielding plate 20 (i.e., the lower the transmittance), leading to a reduction in the dose of X-rays absorbed by the silicon oxide film. The smaller the dose of X-rays absorbed by the silicon oxide film, the longer the lifetime of the circuit element (the transistor). For example, assuming that the lifetime of a transistor in a configuration with no X-ray shielding plate 20 is one to two hours, the lifetime of a transistor in a configuration with the X-ray shielding plate 20 having an effective thickness of 200 μm is approximately one thousand times as long as the above-described lifetime, that is, approximately 40 to 80 days. A proper thickness of the X-ray shielding plate 20 can be determined based on the frequency with which the circuit element on the blanking aperture array member 30 is desired or required to be replaced.

The thicker the X-ray shielding plate 20, the higher the X-ray absorption rate of the X-ray shielding plate 20. The X-ray shielding plate 20 is therefore required to have the apertures 22 having a high aspect ratio. For this reason, for example, as illustrated in FIG. 5, a plurality of thin X-ray shielding plates 20A each having apertures 22A may be stacked.

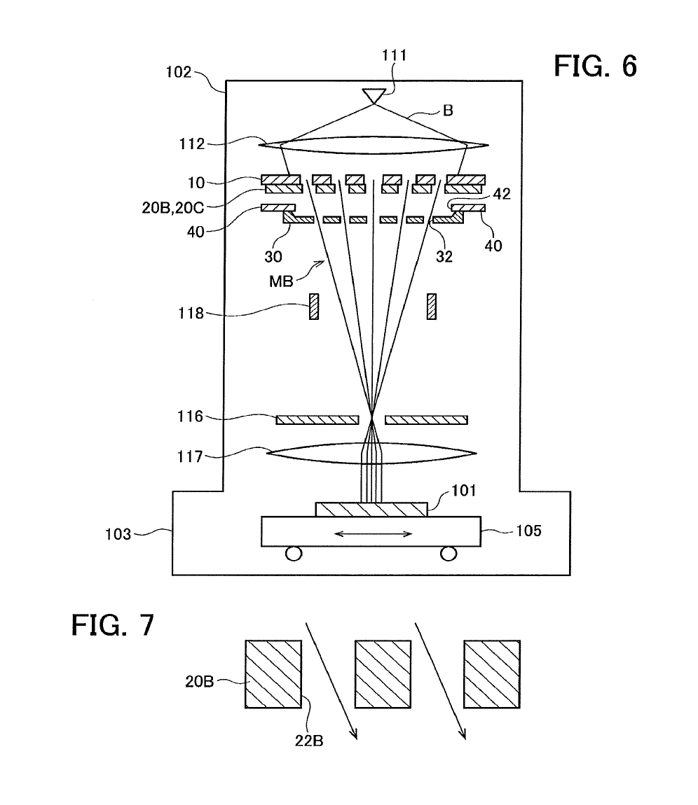

FIG. 6 is a diagram illustrating part of an exemplary configuration of a writing apparatus according to a modification of the embodiment. In the above-described embodiment, as illustrated in FIG. 1, the reducing lens 115 and the objective lens 117 constitute a reduction optical system. In such a configuration, the electron beam B emitted from the electron gun 111 is caused by the illumination lens 112 to be applied substantially perpendicular to the entire shaping aperture array member 10. Any other configuration may be used. FIG. 6 illustrates the configuration in which the reducing lens 115 is not included and the illumination lens 112 and the objective lens 117 constitute the reduction optical system.

The electron beam B emitted from the electron gun 111 is converged by the illumination lens 112 to form a crossover in the central opening of the limiting aperture member 116, and is then applied to the entire shaping aperture array member 10. Multiple beams formed by the shaping aperture array member 10 travel at different angles toward the central opening of the limiting aperture member 116. The diameter of the combination of the multiple beams MB gradually decreases after the multiple beams pass through the shaping aperture array member 10. Consequently, when passing through the blanking aperture array member 30, the multiple beams are arranged at a smaller pitch than the multiple beams formed by the shaping aperture array member 10. The pitch of the apertures 32 is smaller than that of the apertures 12.

The multiple beams MB that have passed through the limiting aperture member 116 are focused by the objective lens 117, thus forming a pattern image at a desired reduction rate. The beams (all of the multiple beams) that have passed through the limiting aperture member 116 are collectively deflected in the same direction by the deflector 118 and are then applied to the respective beam irradiation positions on the sample 101.

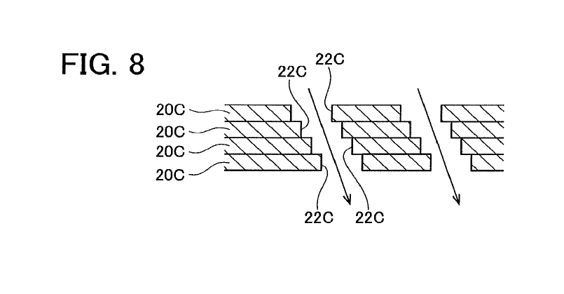

As described above, in the writing apparatus of FIG. 6, each of the multiple beams MB travels at an angle toward the central opening of the limiting aperture member 116. As illustrated in FIGS. 7 and 8, it is therefore preferred that the multiple beams MB be not obstructed by the apertures of the X-ray shielding plate or plates. FIG. 7 illustrates an X-ray shielding plate 20B having a single-layer structure. FIG. 8 illustrates a multi-layer structure including a plurality of thin X-ray shielding plates 20C. The X-ray shielding plate 20B has apertures 22B arranged at a pitch different from that of the apertures 12.

FIG. 8 illustrates an exemplary structure in which the multiple X-ray shielding plates 20C are stacked such that apertures 22C are slightly shifted with each other to coincide with the trajectories of the respective beams. The multiple beams MB travel while turning in the magnetic field. Therefore, preferably, the X-ray shielding plates 20C are arranged such that the apertures 22C of a lower X-ray shielding plate 20C are shifted with the apertures 22C of an upper X-ray shielding plate 20C in x and y directions.

The X-ray shielding plate 20 may have the apertures 22 greater in number than the apertures 12 of the shaping aperture array member 10. Of the apertures 22, the apertures 22 aligned well with the apertures 12 of the shaping aperture array member 10 may be used.

The shaping aperture array member 10 may be made of light element. This allows a reduction in the amount of X-rays produced. For example, it is preferred that the shaping aperture array member 10 be made of silicon carbide (SiC) or carbon (C).

When the thermal expansion coefficient of the material for the shaping aperture array member 10 is (significantly) different from that for the X-ray shielding plate 20, preferably, the shaping aperture array member 10 and the X-ray shielding plate 20 are arranged such that heat is hardly transferred from the shaping aperture array member 10 to the X-ray shielding plate 20. For example, the X-ray shielding plate 20 may be secured to the shaping aperture array member 10 with adhesive having high thermal resistance. The X-ray shielding plate 20 and the shaping aperture array member 10 may be arranged in point contact with each other, thus reducing the area of contact. The shaping aperture array member 10 may be spaced apart from the X-ray shielding plate 20.

The pre-aperture array member 14 may be disposed on the lower surface of the shaping aperture array member 10. The shaping aperture array member 10 and the pre-aperture array member 14 may be separate from each other instead of being integrated with each other.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi charged particle beam writing apparatus comprising:
an emitter emitting a charged particle beam;
a shaping aperture array member having a plurality of first apertures, the shaping aperture array member receiving the charged particle beam in a region including the first apertures and allowing the charged particle beam to partially pass through the first apertures, thus forming multiple beams;
an X-ray shielding plate having a plurality of second apertures through each of which a corresponding one of the multiple beams that have passed through the first apertures passes, the X-ray shielding plate blocking X-rays produced by irradiation of the shaping aperture array member with the charged particle beam; and
a blanking aperture array member having a plurality of third apertures through each of which a corresponding one of the multiple beams that have passed through the first apertures and the second apertures passes, the blanking aperture array member including a blanker in each of the third apertures, the blanker performing blanking deflection on the corresponding beam.

2. The apparatus according to claim 1, wherein the X-ray shielding plate includes a plurality of shielding plates stacked.

3. The apparatus according to claim 2, wherein the third apertures are arranged at a pitch smaller than that of the first apertures, and the pitch of the first apertures differs from that of the second apertures.

4. The apparatus according to claim 3, wherein the shielding plates are stacked such that the second apertures of an upper shielding plate are shifted with the second apertures of a lower shielding plate.

5. The apparatus according to claim 1,
wherein the X-ray shielding plate is secured to the shaping aperture array member, and
wherein the shaping aperture array member includes silicon, and the X-ray shielding plate includes tungsten.

6. The apparatus according to claim 1, wherein the second apertures have a larger diameter than the first apertures.

7. The apparatus according to claim 1, further comprising:
a pre-aperture array member disposed on the shaping aperture array member,
wherein the pre-aperture array member has a plurality of fourth apertures for beam passage aligned with the first apertures.

8. The apparatus according to claim 7, wherein the fourth apertures have a larger diameter than the first apertures.

9. The apparatus according to claim 1, wherein the X-ray shielding plate includes tungsten, gold, tantalum, lead, hafnium, or platinum.

10. The apparatus according to claim 1, wherein the shaping aperture array member includes silicon carbide or carbon.
